(19) United States
(12) Patent Application Publication
(10) Pub. No.: US 2011/0240462 A1
(43) Pub. Date: Oct. 6, 2011

(54) DEPOSITION APPARATUS AND METHOD FOR MANUFACTURING SEMICONDUCTOR DEVICE

(75) Inventor: Shunpei Yamazaki, Tokyo (JP)

(73) Assignee: SEMICONDUCTOR ENERGY LABORATORY CO., LTD., Atsugi-shi (JP)

(21) Appl. No.: 13/076,825

(22) Filed: Mar. 31, 2011

(30) Foreign Application Priority Data
Apr. 2, 2010 (JP) 2010-085714

(51) Int. Cl. C23C 14/34

(52) U.S. Cl. 204/192.25; 204/298.02; 204/298.13

(57) ABSTRACT

An object of one embodiment of the present invention is to provide a deposition apparatus for depositing an oxide semiconductor film into which impurities are not mixed. Another object is to provide a method for manufacturing a semiconductor device including an oxide semiconductor film into which impurities are not mixed. Impurities are removed from an environment including a deposition apparatus, whereby a gas containing impurities may be prevented from leaking from the outside of the deposition apparatus to the inside thereof. In addition, an oxide semiconductor layer containing reduced impurities which is deposited by the apparatus may be applied to the semiconductor device.

### BACKGROUND OF THE INVENTION

1. Field of the Invention

The present invention relates to a deposition apparatus. Further, the present invention relates to a method for manufacturing a semiconductor device.

Note that a semiconductor device in this specification refers to all devices which can function by utilizing semiconductor characteristics, and electro-optical devices such as display devices, semiconductor circuits, and electronic devices are all semiconductor devices.

2. Description of the Related Art

In recent years, the development of semiconductor integrated circuits such as LSIs, CPUs, or memories which are used for semiconductor devices has been proceeding. The semiconductor integrated circuit is, for example, an assemblage of semiconductor devices each provided with an electrode which is a connection terminal, which includes a transistor or a memory over a substrate such as a semiconductor wafer.

A semiconductor integrated circuit (IC chip) such as an LSI, a CPU, or a memory is mounted on a circuit board, for example, a printed wiring board, to be used as one of components of a variety of electronic devices.

Further, a semiconductor device capable of transmitting data has been developed. Such a semiconductor device is called a wireless tag, an RFID tag, or the like, and for example, a semiconductor device in which a semiconductor integrated circuit (an IC chip) and an antenna are connected to each other is put into practical use.

A silicon-based semiconductor material has been known as a semiconductor material that can be used for a transistor; however, an oxide semiconductor has attracted attention as another material. As materials of the oxide semiconductor, zinc oxide and substances containing zinc oxide are known. In addition, transistors formed using an oxide semiconductor having an electron carrier concentration lower than 10¹⁸/cm³ are disclosed (Patent Documents 1 to 3).

### REFERENCE

### Patent Document

[Patent Document 1] Japanese Published Patent Application No. 2006-165527
[Patent Document 2] Japanese Published Patent Application No. 2006-165528
[Patent Document 3] Japanese Published Patent Application No. 2006-165529

### SUMMARY OF THE INVENTION

In order to obtain a semiconductor device with low power consumption, extremely low off-state current of a semiconductor device such as a transistor is required. The thin film transistors disclosed in the above Patent Documents do not have a sufficient high on/off ratio. This is because even when the electron carrier concentration is lower than 10¹⁸/cm³, the oxide semiconductor is a substantially n-type oxide semiconductor and its off-state current is difficult to reduce.

In order to reduce the off-state current of a transistor including an oxide semiconductor to an extremely low level, the hydrogen atom concentration in an oxide semiconductor film and a layer in contact with the oxide semiconductor film needs to be sufficiently reduced without entry of a compound having a hydrogen atom, such as a compound containing an OH bond, into the film and the layer.

However, even when a deposition apparatus is evacuated to a high vacuum level, the air might leak from the outside of the deposition apparatus to the inside thereof through a connection portion or the like of the deposition apparatus, and impurities in the deposition apparatus cannot be sufficiently removed in some cases. A film deposited using such a deposition apparatus becomes a film containing impurities. In other words, there is always a possibility that a film deposited using a deposition apparatus which is disposed in the air may be contaminated by impurities contained in the air.

An example of a unit for removing impurities mixed during deposition into the film is heat treatment. However, adding heat treatment to a manufacturing process of a semiconductor device leads to problems such as an increase in manufacturing steps, which causes an increase in time required to manufacture a device, and an increase in energy consumption for the heat treatment.

In addition, it is difficult to completely remove impurities once mixed during deposition, e.g., a compound containing a hydrogen atom such as water, from the film by any method.

An object of one embodiment of the present invention is to provide a deposition apparatus by which an oxide semiconductor film into which impurities are not mixed is deposited. Another object of one embodiment of the present invention is to provide a method for manufacturing a semiconductor device including an oxide semiconductor film into which impurities are not mixed.

In order to achieve any of the above-described objects, the present invention focuses on an environment including the deposition apparatus is focused. Specifically, impurities are removed from the environment including the deposition apparatus, whereby a gas containing impurities is prevented from leaking from the outside of the deposition apparatus to the inside thereof. In addition, an oxide semiconductor layer deposited by the apparatus may be applied to the semiconductor device.

A deposition apparatus of one embodiment of the present invention includes a deposition chamber, a partition provided to enclose the deposition chamber, and a space between the deposition chamber and the partition. Further, the partition includes a unit for supplying the space with a gas, in which the concentration of a compound containing a hydrogen atom is 1 ppm or lower, and a pressure adjusting unit for adjusting the pressure in the space to atmospheric pressure or a higher pressure. Furthermore, the deposition chamber includes a target holding portion for fixing a sputtering target of metal oxide and a vacuum evacuation unit.

The pressure in the space enclosed by the partition is kept at atmospheric pressure or a higher pressure with the gas, in which the concentration of the compound containing a hydrogen atom is 1 ppm or lower, whereby the compound containing a hydrogen atom is prevented from entering the space from the air which is atmospheric pressure and the compound containing a hydrogen atom can be efficiently prevented from entering the deposition chamber.

Another embodiment of the present invention is the above deposition apparatus which further includes a load lock chamber including a substrate holding portion provided with a heating unit for heating a substrate and a vacuum evacuation unit.

By providing the load lock chamber for the above deposition apparatus, a state in which the deposition chamber is evacuated to a vacuum level can be kept in transferring the substrate; accordingly, cleanliness of the deposition chamber can be kept.

A deposition apparatus of another embodiment of the present invention includes a plurality of deposition chambers, a partition provided so as to enclose at least one deposition chamber, and a space between the at least one deposition chamber and the partition. The deposition apparatus further includes a load lock chamber which includes a substrate holding portion provided with a heating unit for heating a substrate and a vacuum evacuation unit. In addition, the partition includes a unit for supplying the space with a gas, in which the concentration of a compound containing a hydrogen atom is 1 ppm or lower, and a pressure adjusting unit for adjusting the pressure in the space to atmospheric pressure or a higher pressure. The at least one deposition chamber is provided with a target holding portion for fixing a sputtering target and a vacuum evacuation unit, and another deposition chamber is provided with a target holding portion for fixing a sputtering target of metal oxide. Moreover, in the space, the deposition apparatus includes a transfer unit including a vacuum evacuation unit, which is connected to the load lock chamber and the deposition chamber through gate valves.

The pressure in the space enclosed by the partition is kept at atmospheric pressure or a higher pressure with a gas, in which the concentration of the compound containing a hydrogen atom is 1 ppm or lower, whereby the compound containing a hydrogen atom is prevented from entering the space from the air which is atmospheric pressure and the compound containing a hydrogen atom can be efficiently prevented from entering the plurality of deposition chambers and the transfer unit.

According to another embodiment of the present invention, in any of the above deposition apparatuses, a rare gas is contained in the gas, in which the concentration of the compound containing a hydrogen atom is 1 ppm or lower.

When the main component of the gas filling the space enclosed by the partition is a rare gas, a gas which leaks to the deposition apparatus can be a rare gas. Since a rare gas has no adverse effects similarly to a deposition gas in deposition of an oxide semiconductor film, a semiconductor device in which entry of impurities is extremely suppressed can be manufactured.

According to another embodiment of the present invention, in any of the above deposition apparatuses, argon is contained in the gas, in which the concentration of the compound containing a hydrogen atom is 1 ppm or lower.

When the main component of the gas filling the space enclosed by the partition is argon, since argon is easily obtained as compared with helium or the like which is also a rare gas, deposition can be performed at low cost.

According to another embodiment of the present invention, in any of the above deposition apparatuses, the partition is a flexible bag or a chamber.

When a flexible bag is used as the above partition, the above effects can be easily provided for an existing apparatus as compared with a chamber formed using metal or the like. On the other hand, when a chamber formed using metal or the like is used as the above partition, the pressure in the space can be adjusted in a wide range.

Another embodiment of the present invention is a method for manufacturing a semiconductor device including the following steps: transferring a substrate to a deposition apparatus evacuated to a vacuum level and provided in a space to which a gas, in which the concentration of a compound containing a hydrogen atom is 1 ppm or lower is introduced, and the pressure in the space is kept at atmospheric pressure or a higher pressure; introducing a high-purity sputtering gas into the deposition chamber; and forming an oxide semiconductor film over a substrate by a sputtering method.

By the above method, the deposition can be performed in an environment in which the concentration of the compound containing a hydrogen atom is extremely low in the deposition chamber and an oxide semiconductor film with reduced hydrogen atom concentration can be formed.

Another embodiment of the present invention is a method for manufacturing a semiconductor device including the following steps: transferring a substrate to a load lock chamber; evacuating the load lock chamber to a vacuum level; performing heating treatment on the substrate; transferring the substrate to a first deposition chamber provided in a space and evacuated to a vacuum level, in which the space is supplied with a gas including a compound containing a hydrogen atom, the concentration of the compound in the gas is lower than or equal to 1 ppm, and a pressure in the space is kept at atmospheric pressure or a higher pressure; introducing a high-purity sputtering gas into the first deposition chamber; forming a gate insulating film over the substrate; evacuating the first deposition chamber to a vacuum level; transferring the substrate to a second deposition chamber provided in the space and evacuated to a vacuum level; introducing a high-purity sputtering gas into the second deposition chamber; and forming an oxide semiconductor film over the gate insulating film by a sputtering method.

Through the above heat treatment on the substrate, the compound containing a hydrogen atom adsorbed onto the substrate can be detached and removed. In addition, the gate insulating film and the oxide semiconductor film can be successively deposited in an environment in which the concentration of the compound containing a hydrogen atom is extremely low, so that a stacked film can be formed in which the hydrogen atom concentration in the insulating film, in the oxide semiconductor film, and at an interface therebetween is reduced.

Another embodiment of the present invention is a method for manufacturing a semiconductor device further including the following steps: evacuating the second deposition chamber to a vacuum level after the oxide semiconductor film is formed; transferring the substrate to a third deposition chamber provided in the space and evacuated to a vacuum level; introducing a high-purity sputtering gas into the third deposition chamber; and forming a conductive film over the oxide semiconductor film by a sputtering method.

By the above method, an oxide semiconductor film and a conductive film can be successively formed in an environment in which the concentration of the compound containing a hydrogen atom is extremely low without exposing the substrate to the air, so that a semiconductor device can be manufactured in which the hydrogen atom concentration at an interface between the oxide semiconductor film and the conductive film and in the conductive film is reduced.

According to one embodiment of the present invention, a deposition apparatus used for depositing an oxide semiconductor film into which impurities are not mixed can be provided. According to one embodiment of the present invention, a method for manufacturing a semiconductor device including an oxide semiconductor film into which impurities are not mixed can be provided.

### BRIEF DESCRIPTION OF THE DRAWINGS

FIG. 1 illustrates a deposition apparatus according to one embodiment of the present invention.

FIG. 2 illustrates an apparatus for successive deposition according to one embodiment of the present invention.

FIGS. 3A to 3C illustrate a transistor which is manufactured by a manufacturing method according to one embodiment of the present invention.

FIGS. 4A to 4E illustrate a method for manufacturing a transistor according to one embodiment of the present invention.

FIGS. 5A to 5E illustrate a method for manufacturing a transistor according to one embodiment of the present invention.

FIGS. 6A to 6E illustrate a method for manufacturing a transistor according to one embodiment of the present invention.

FIG. 7 illustrates a deposition apparatus according to one embodiment of the present invention.

FIG. 8 illustrates an apparatus for successive deposition according to one embodiment of the present invention.

### DETAILED DESCRIPTION OF THE INVENTION

Hereinafter, embodiments of the present invention are described with reference to the accompanying drawings. Note that the invention disclosed in this specification is not limited to the following description because it will be easily understood by those skilled in the art that various changes and modifications can be made without departing from the spirit and scope of the present invention. Therefore, the present invention disclosed should not be construed as being limited to the description below of embodiments and examples. In the drawings for explaining the embodiments, the same parts or parts having a similar function are denoted by the same reference numerals, and description of such parts is not repeated.

### Embodiment 1

In this embodiment, a deposition apparatus according to one embodiment of the present invention will be described with reference to drawings.

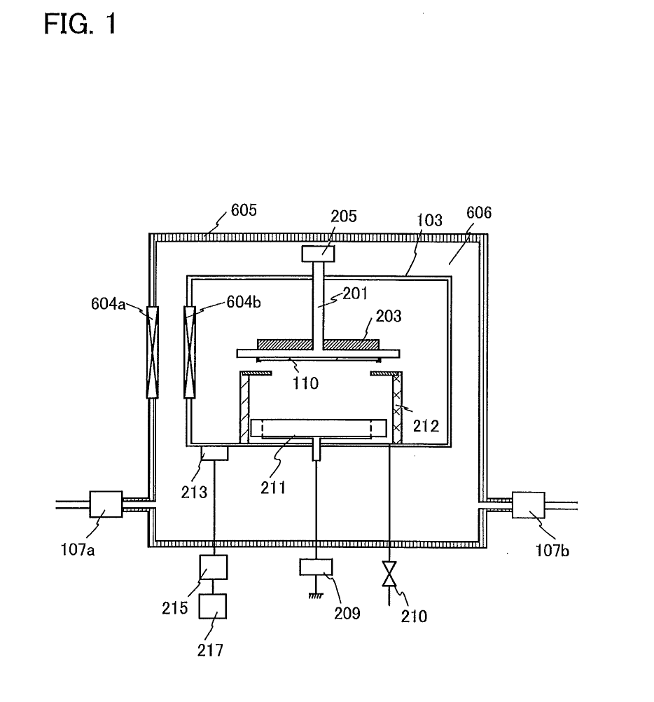

FIG. 1 is a schematic cross-sectional view of a deposition apparatus of this embodiment.

The deposition apparatus illustrated in FIG. 1 is provided with a deposition chamber 103 inside a partition 605, and a space 606 between the partition 605 and the deposition chamber 103.

First, a structure of the partition 605 which encloses the deposition chamber 103 is described.

The partition 605 includes a gas introduction unit 107a for supplying a gas to the space 606, a pressure adjusting unit 107b, and an entrance 604a.

The partition 605 is provided to form the space 606 between the deposition chamber 103 and the air. There is no particular limitation on the partition 605 as long as it does not transmit impurities contained in the air. For example, the partition 605 may be formed of metal such as iron, aluminum, or stainless steel. Alternatively, a flexible bag having a sufficient thickness which does not transmit impurities contained in the air or an anti-transmissive film (barrier film) may be used. Note that as an example of impurities contained in the air, a compound containing a hydrogen atom such as water can be given in the case where an oxide semiconductor layer is deposited.

The entrance 604a is an entrance for transferring a substrate to be processed to and from the partition 605. The entrance 604a includes a door which can be opened and closed, and when the substrate is transferred to or from the partition 605, the door is opened to form an opening in the partition 605. There is a concern that by opening the entrance 604a, the pressure in the space 606 is reduced to atmospheric pressure and impurities contained in the air are diffused into a sealing gas in the space 606. Therefore, the sealing gas in the space 606 is sufficiently replaced with a high-purity gas after the entrance 604a is opened, and for example, the concentration of a compound containing a hydrogen atom is preferably 1 ppm or lower, more preferably 0.1 ppm or lower.

The pressure adjusting unit 107b may include a pressure sensor, a valve, and an exhaust line, for example. The pressure can be controlled in the following manner; when the internal pressure is higher than a set value, the valve is opened, and when the internal pressure is lower than a set value, the valve is closed.

The sealing gas containing a rare gas such as argon can be introduced into the space 606 using the gas introduction unit 107a and the pressure adjusting unit 107b. It is preferable that the sealing gas do not contain a compound containing a hydrogen atom, and the concentration of the compound containing a hydrogen atom is preferably 1 ppm or lower, more preferably 0.1 ppm or lower.

Part of the sealing gas leaks to the deposition chamber 103 through a connection portion of the deposition chamber 103 or a joint portion between pipes provided for the deposition chamber 103. A main component of the leaking sealing gas is a rare gas such as argon.

In addition, oxygen, nitrogen, or a compound containing a hydrogen atom such as H₂O leaks from the air to the space 606 as an impurity through a connection portion of the partition 605 or a joint portion between pipes provided for the partition 605; however, the pressure in the space 606 is set to larger than atmospheric pressure using the gas introduction unit 107a and the pressure adjusting unit 107b, so that the adverse effect can be suppressed.

Next, the deposition chamber 103 will be described. The deposition chamber 103 includes a substrate holding portion 201 for holding a substrate 110 which is a substrate to be processed, a substrate heating unit 203, a substrate rotating unit 205, a sputtering target 211 which is held by a target holding portion, an attachment protection plate 212, a main valve 213, and an entrance 604b. Note that a shutter (not illustrated) is provided between the sputtering target 211 and the substrate 110. In addition, a power source 209, a gas introduction unit 210, an automatic pressure controlling device 215, and an evacuation unit 217 are provided outside the partition 605, and are directly connected to the deposition chamber 103 using a pipe or the like.

As the evacuation unit 217, an evacuation unit such as a cryopump is preferably used, for example. This is because the amount of impurities mixed into the film can be suppressed lower in the case where an oxide semiconductor layer is deposited.

The gas introduction unit 210 may be connected to a gas supply line through such as an electromagnetic valve controlled by a mass flow controller or the like, for example. A gas in which mixture ratio of a plurality of gasses is controlled can be introduced into the deposition chamber 103 using a mass flow controller. Note that in order to prevent an impurity from entering the deposition chamber 103, a high-purity gas is used as a gas which is introduced into the deposition chamber 103. The gas which is introduced into the deposition chamber 103 is highly purified by a gas refiner before being introduced into the apparatus. Accordingly, impurities such as water in the gas can be removed in advance to prevent these impurities from being introduced into the apparatus.

The substrate holding portion 201 has a function of holding the substrate 110. In addition, the substrate holding portion 201 includes the substrate heating unit 203. As the substrate heating unit 203, a unit for heating an object to be processed by heat conduction or heat radiation from a heater such as a resistance heater, or a unit for heating an object to be processed by radiation of light (an electromagnetic wave) emitted from a lamp may be used. The deposition can be performed while the substrate 110 is heated by the substrate heating unit 203.

The substrate rotating unit 205 can rotate the substrate 110. The deposition is preferably performed while the substrate 110 is rotated because the uniformity of a film thickness is increased.

The attachment protection plate 212 prevents a deposition material which is not attached to the substrate in the deposition from being attached to the inner wall of the deposition chamber 103 and causing generation of dust. As the material of the attachment protection plate 212, metal such as iron, aluminum, or stainless steel can be used.

Note that the deposition chamber 103 may include a unit (not illustrated) for heating a wall surface around the substrate holding portion 201. The inner wall of the deposition chamber is heated regularly, and impurities adsorbed onto the inner wall can be detached; accordingly, a high vacuum level can be achieved.

The entrance 604b is an entrance for transferring a substrate to be processed to and from the deposition chamber 103. The entrance 604b includes a door which can be opened and closed, and when the substrate is transferred to or from the deposition chamber 103, the door is opened to form an opening in the deposition chamber 103.

Note that the deposition chamber 103 may include a load lock chamber for transferring the substrate 110 to the deposition apparatus and a transfer chamber for transferring the substrate from the load lock chamber to the deposition chamber.

Next, a deposition apparatus including the deposition chamber, the transfer chamber, and the load lock chamber which are described above is described.

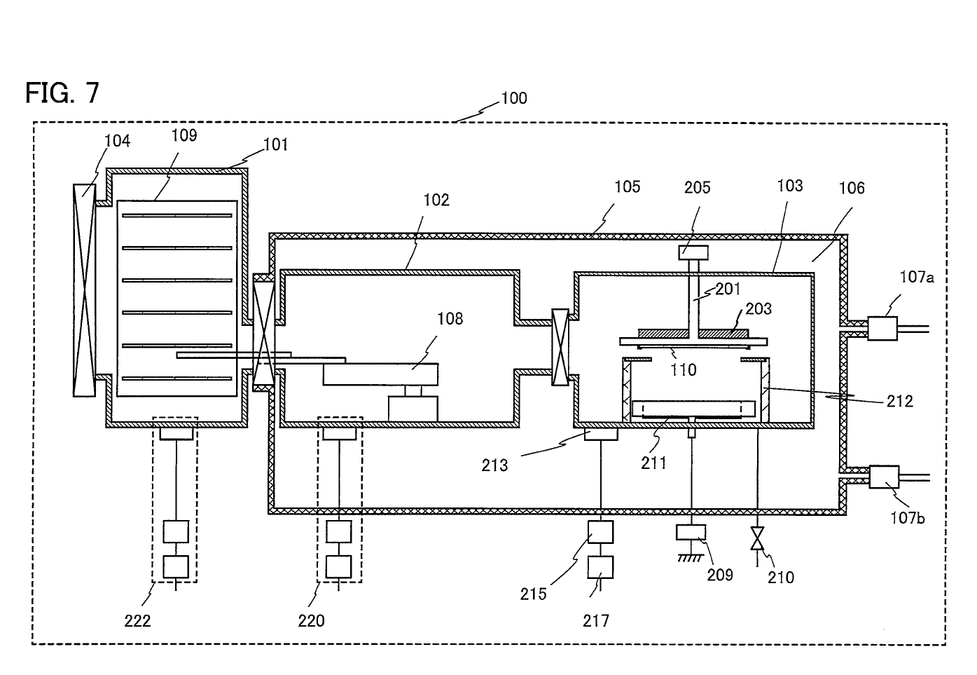

FIG. 7 is a schematic side view of the deposition apparatus of this embodiment.

A deposition apparatus 100 illustrated in FIG. 7 includes a load lock chamber 101 and a partition 105. A transfer chamber 102 connected to the load lock chamber 101 and a deposition chamber 103 connected to the transfer chamber 102 are provided inside the partition 105, and a gate valve is provided at each of connection portions. In addition, a space 106 is provided between the partition 105, and the transfer chamber 102 and the deposition chamber 103. Further, the partition 105 includes the pressure adjusting unit 107b and the gas introduction unit 107a for introducing a gas into the space 106.

The load lock chamber 101 includes a substrate holding portion 109 including a substrate heating unit, an evacuation unit 222, and a gas introduction unit (not illustrated). Note that in the load lock chamber 101, a gate valve 104 for separating the load lock chamber 101 and the outside of the deposition apparatus 100 is provided. Further, the gate valve for separating the load lock chamber 101 and the transfer chamber 102 is provided.

In the load lock chamber 101, a substrate is transferred to or from the deposition apparatus and a substrate before treatment can be preheated. Further, the load lock chamber 101 can be evacuated using the evacuation unit 222. The substrate before the treatment is preheated while the load lock chamber 101 is evacuated, so that impurities adsorbed onto the substrate can be detached and removed. Note that examples of the impurities are hydrogen, a compound containing a hydrogen atom such as H₂O, and a compound containing a carbon atom. The temperature for the preheating is from higher than or equal to room temperature and lower than or equal to 600° C., preferably from higher than or equal to 100° C. and lower than or equal to 400° C.

The transfer chamber 102 includes a transfer robot 108 and an evacuation unit 220 and serves as a delivery chamber for transferring the substrate 110 between the load lock chamber 101 and the deposition chamber 103.

The transfer chamber 102 can be evacuated to a vacuum level using the evacuation unit 220 provided for the transfer chamber 102. The transfer chamber is evacuated to a vacuum level, whereby the substrate from which impurities are removed by the preheating can be prevented from being contaminated again in transferring.

The partition 105 has a function similar to the above-described partition 605. Similarly, the space 106 has a function similar to the above-described space 606. In other words, the partition 105 has a function of suppressing entry of an impurity from the air into the space 106: with the gas introduction unit 107a and the pressure adjusting unit 107b which are provided for the partition 105, a sealing gas containing a rare gas can be introduced into the space 106 so that the pressure in the space 106 is atmospheric pressure or a higher pressure.

The transfer chamber 102 is provided inside the partition 105, similarly to the deposition chamber 103. Therefore, similarly to the deposition apparatus, by introducing the sealing gas containing a rare gas such as argon into the space 106 so that the pressure in the space 106 is atmospheric pressure or a higher pressure, a main component of a gas leaking to the transfer chamber 102 through a connection portion of the transfer chamber 102 or a joint portion between pipes provided for the transfer chamber 102 is a rare gas such as argon.

Next, a method for forming an oxide semiconductor film over a glass substrate using the deposition apparatus 100 is described. In this embodiment, the case where the oxide semiconductor film is deposited in the deposition chamber 103 by a sputtering method is described. However, the kind of the film is not limited to an oxide semiconductor film, and an oxide insulating film, a nitride insulating film, or the like can be deposited by changing the sputtering target 211 or the like.

With the use of the deposition apparatus 100, the oxide semiconductor can be highly purified so as to contain impurities that are not main components of the oxide semiconductor as little as possible, and an i-type (intrinsic) or substantially i-type (intrinsic) oxide semiconductor can be obtained. In other words, a highly purified i-type (intrinsic) oxide semiconductor, or an oxide semiconductor close thereto, is obtained not by adding an impurity but by preventing an impurity from being contained in the semiconductor as much as possible.

The number of carriers in the highly purified oxide semiconductor can be significantly small (close to zero). Specifically, the carrier concentration can be reduced to lower than 1×10¹²/cm³, preferably lower than 1×10¹¹/cm³. Further, the hydrogen concentration in the highly purified oxide semiconductor is lower than 1×10¹⁶ atoms/cm³.

First, a sealing gas containing argon, in which the concentration of a compound containing a hydrogen atom is 1 ppm or lower, is introduced into the space 106 using the gas introduction unit 107a provided for the partition 105. At the same time, the pressure in the space 106 is adjusted to atmospheric pressure or a higher pressure using the pressure adjusting unit 107b.

Note that argon is used here as the sealing gas; however, this embodiment is not limited thereto, and another rare gas can be used.

Next, in each of the transfer chamber 102 and the deposition chamber 103, the pressure is reduced by the evacuation unit provided for each chamber.

In order to detach impurities adsorbed onto the inner wall of the deposition chamber 103, the inner wall of the deposition chamber 103 may be subjected to heat treatment regularly.

Next, the gate valve 104 between the load lock chamber 101 and the outside is opened, and the substrate 110 is transferred to the load lock chamber 101. After the substrate 110 is transferred, the pressure in the chamber is reduced using the evacuation unit 222 connected to the load lock chamber 101, and the substrate 110 is preheated using the substrate heating unit to detach and remove impurities attached to the substrate 110.

Although there is no particular limitation on a substrate used as the substrate 110, a glass substrate of barium borosilicate glass, aluminoborosilicate glass, or the like is used.

Subsequently, the substrate 110 on which the preheating is finished is transferred to the deposition chamber 103 through the transfer chamber 102 using the transfer robot 108.

First, the gate valve between the load lock chamber 101 and the transfer chamber 102 is opened, the substrate 110 is transferred to the transfer chamber 102 using the transfer robot 108, and the gate valve is closed. Next, the gate valve between the transfer chamber 102 and the deposition chamber 103 is opened, and in a similar manner, the substrate 110 is transferred to the deposition chamber 103.

Note that after the substrate 110 is transferred, the inside of the load lock chamber 101 which is evacuated to a vacuum level may be filled with a rare gas so that the pressure in the load lock chamber 101 is atmospheric pressure or a higher pressure. Thus, entry of an atmospheric component containing an impurity from the air into the load lock chamber 101 can be suppressed.

The substrate 110 is transferred to the substrate holding portion 201 in the deposition chamber 103. A substrate holder (not illustrated) in the substrate holding portion 201 is moved vertically by a vertical driving mechanism and can fix the substrate. As illustrated in FIG. 7, it is preferable to adopt a face-down manner (a manner in which deposition is performed while a surface to be subjected to deposition of a substrate points downward) because attachment of dust or the like to the substrate 110 can be suppressed.

After the substrate 110 is transferred, the gate valve between the transfer chamber 102 and the deposition chamber 103 is closed.

A high-purity sputtering gas is introduced into the deposition chamber 103 while the pressure in the deposition chamber 103 is controlled using the evacuation unit 217, the main valve 213, the automatic pressure controlling device 215, and the gas introduction unit 210 of the deposition chamber 103, and an oxide semiconductor film is deposited over the substrate 110 by a sputtering method.

The power source 209 used for sputtering may be either a DC (direct current) power source or an RF (radio frequency) power source. For example, in the deposition chamber 103, an RF sputtering method in which an RF power source is used is employed in the case where an insulating film is deposited, and a DC sputtering method in which a DC power source is used is employed in the case where a conductive film containing metal is deposited.

After the deposition, the deposition chamber 103 is evacuated again using the evacuation unit 217 to keep clean. When the deposition chamber 103 is kept clean after the deposition, impurities adsorbed onto a surface of the deposited oxide semiconductor film is efficiently reduced.

Then, the substrate 110 on which deposition treatment is finished is transferred from the deposition chamber 103 to the substrate holding portion 109 in the load lock chamber 101 through the transfer chamber 102, using the transfer robot 108 in a manner similar to that of transferring the substrate 110 to the deposition chamber 103. After the gate valve between the load lock chamber 101 and the transfer chamber 102 is closed, the pressure in the load lock chamber 101 is set to atmospheric pressure using the evacuation unit 222 provided for the load lock chamber 101. After that, the gate valve 104 between the lock chamber 101 and the outside is opened, and the substrate 110 is taken out.

Through the above steps, the oxide semiconductor film is deposited over the glass substrate.

Note that when the substrate 110 is transferred between the load lock chamber 101 and the transfer chamber 102, the substrate may be transferred in a state where the inside of each chamber is filled with a rare gas and the pressures of the chambers are set to the same pressure which is atmospheric pressure or a higher pressure. Thus, entry of an atmospheric component containing an impurity from the air into the load lock chamber 101 in transferring the substrate can be suppressed.

As described above, the deposition apparatus of this embodiment includes a space into which a sealing gas containing a rare gas can be introduced and which is provided by the partition for separating the air, and the transfer chamber and the deposition chamber. A sealing gas whose main component is a rare gas, in which the concentration of a compound containing a hydrogen atom is 1 ppm or lower, is introduced into the space so that the pressure is adjusted to atmospheric pressure or a higher pressure, whereby the compound containing a hydrogen atom can be prevented from entering the transfer chamber and the deposition chamber.

By depositing an oxide semiconductor film with such a deposition apparatus, impurities are not mixed into the oxide semiconductor film and an interface between a substrate and the oxide semiconductor film, whereby a highly purified oxide semiconductor film in which the hydrogen concentration is sufficiently reduced can be formed. Such a highly purified oxide semiconductor film is used for a transistor, so that a transistor with low off-state current and low power consumption can be provided.

### Embodiment 2

In this embodiment, an apparatus for successive deposition according to one embodiment of the present invention will be described with reference to drawings.

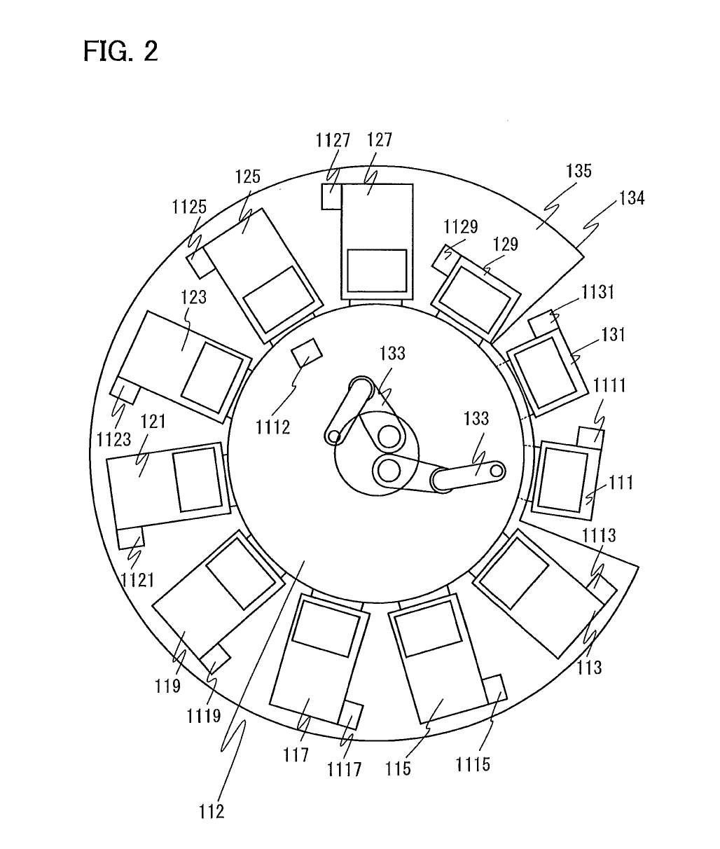

FIG. 2 is a schematic top view of an apparatus for successive deposition of this embodiment.

The apparatus for successive deposition illustrated in FIG. 2 includes a first load lock chamber 111, a second load lock chamber 131, and a partition 134. Further, the apparatus for successive deposition illustrated in FIG. 2 includes a transfer chamber 112, a plurality of deposition chambers (which correspond to a first deposition chamber 113, a second deposition chamber 115, a third deposition chamber 117, a fourth deposition chamber 121, and a fifth deposition chamber 127 in FIG. 2), a plurality of heating chambers (which correspond to a first heating chamber 119 and a second heating chamber 123 in FIG. 2), a treatment chamber 125, a substrate standby chamber 129, and a substrate transfer unit 133, inside the partition 134. A space 135 is provided between the partition 134, and the transfer chamber 112, the plurality of deposition chambers, the plurality of heating chambers, the treatment chamber 125, the substrate standby chamber 129, and the substrate transfer unit 133. Although not illustrated, the apparatus for successive deposition of this embodiment includes a unit for heating the inner wall of the apparatus at higher than or equal to 300° C.

The first load lock chamber 111, the transfer chamber 112, the plurality of deposition chambers, the plurality of heating chambers, the treatment chamber 125, the substrate standby chamber 129, and the second load lock chamber 131 include evacuation units 1111 to 1131, respectively. The evacuation units are selected in accordance with the application of each chamber. The evacuation units may be the one provided with an entrapment pump, a turbo pump provided with a cold trap, or the like. In particular, the evacuation unit is preferably provided with the entrapment pump. An example of the entrapment pump is a pump provided with an entrapment unit such as a cryopump, a sputtering ion pump, or a titanium sublimation pump.

In this embodiment, the first load lock chamber 111 is a chamber where a substrate holder which stores a substrate before treatment is placed, and the second load lock chamber 131 is a chamber where a substrate holder which stores a substrate after the treatment is placed. However, the deposition apparatus according to one embodiment of the present invention is not limited thereto, and transferring the substrate may be performed in one load lock chamber.

Although not illustrated, the first load lock chamber 111 includes a substrate heating unit. The evacuation unit 1111 and the substrate heating unit are used together and a substrate before the treatment is preheated while the first load lock chamber 111 is evacuated, so that impurities attached to the substrate can be detached and removed.

The transfer chamber 112 serves as a delivery chamber for transferring a substrate from one chamber to another chamber using the substrate transfer unit 133. The apparatus for successive deposition of this embodiment has two substrate transfer units; however, the number of substrate transfer units may be an arbitrary number which is one or more.

The heating chambers (the first heating chamber 119 and the second heating chamber 123) each include a unit for heating a substrate. The apparatus for successive deposition of this embodiment has two heating chambers; however, the number of heating chambers may be an arbitrary number which is one or more.

The treatment chamber 125 is a chamber where oxygen radical treatment can be performed. Oxygen radicals may be supplied by a plasma generating apparatus including oxygen or an ozone generating apparatus. By exposing a thin film to the produced oxygen radicals or oxygen, the surface of the film can be modified. Further, the treatment performed in the treatment chamber is not limited to the oxygen radical treatment. In the apparatus for successive deposition, the treatment chamber is not necessarily provided, or a plurality of treatment chambers may be provided.

The substrate standby chamber 129 is a chamber where a substrate in a process of successive deposition can be on standby. The substrate standby chamber 129 may have a cooling unit. By providing the cooling unit, a substrate which has been heated for the deposition or the like can be cooled sufficiently in the substrate standby chamber 129. The cooling may be performed by introducing helium, neon, argon, or the like into the substrate standby chamber 129. Note that it is preferable that a compound containing a hydrogen atom such as water or hydrogen be not included in a nitrogen gas or a rare gas such as helium, neon, or argon which is used for the cooling. The purity of a nitrogen gas or a rare gas such as helium, neon, or argon is preferably 6N (99.9999%) or higher, more preferably 7N (99.99999%) or higher (that is, the impurity concentration is 1 ppm or lower, preferably 0.1 ppm or lower). In the apparatus for successive deposition, the substrate standby chamber is not necessarily provided.

The apparatus for successive deposition according to one embodiment of the present invention includes a plurality of deposition chambers. The apparatus for successive deposition in FIG. 2 includes five deposition chambers (the first deposition chamber 113, the second deposition chamber 115, the third deposition chamber 117, the fourth deposition chamber 121, and the fifth deposition chamber 127); however the number of the deposition chambers is not limited thereto, and can be determined as appropriate depending on the number of films for successive deposition.

For the deposition performed in the deposition chamber, any of a variety of deposition methods such as a sputtering method, a vacuum evaporation method, and a plasma CVD method can be used in accordance with a kind of a film to be formed. For example, a silicon nitride film can be deposited in the first deposition chamber 113 by a sputtering method; a silicon oxide film can be deposited in the second deposition chamber 115 by a sputtering method; oxide semiconductor films can be deposited in the third deposition chamber 117 and the fourth deposition chamber 121 by a sputtering method; and a conductive film can be deposited in the fifth deposition chamber 127 by a sputtering method.

Next, a structure of the partition 134 which encloses chambers (the transfer chamber 112, the plurality of deposition chambers, the plurality of heating chambers, the treatment chamber 125, and the substrate standby chamber 129) other than the load lock chambers is described.

The partition 134 is provided to form the space 135 between the air and each chamber other than the load lock chambers. There is no particular limitation on the partition 134 as long as it does not transmit impurities contained in the air. For example, the partition 134 may be formed of metal such as iron, aluminum, or stainless steel. Alternatively, a flexible bag having a sufficient thickness which does not transmit impurities contained in the air or an anti-transmissive film (barrier film) may be used. Note that as an example of impurities contained in the air, a compound containing a hydrogen atom such as water can be given in the case where an oxide semiconductor film is deposited.

Although not illustrated, the partition 134 includes a gas introduction unit and a pressure adjusting unit.

The pressure adjusting unit may include a pressure sensor, a valve, and an exhaust line, for example. The pressure can be controlled in the following manner; when the internal pressure is higher than a set value, the valve is opened, and when the internal pressure is lower than a set value, the valve is closed.

The sealing gas containing a rare gas such as argon can be introduced into the space 135 using the gas introduction unit and the pressure adjusting unit. The sealing gas does not preferably include a compound containing a hydrogen atom, and the concentration of the compound containing a hydrogen atom is 1 ppm or lower, preferably 0.1 ppm or lower.

Part of the sealing gas leaks to the chambers other than the load lock chambers through a connection portion of each chamber or a joint portion between pipes provided for each chamber. A main component of the leaking sealing gas is a rare gas such as argon.

In addition, oxygen, nitrogen, or a compound containing a hydrogen atom such as H₂O leaks from the air to the space 135 as an impurity through a connection portion of the partition 134 or a joint portion between pipes provided for the partition 134; however, the pressure in the space 135 is set to larger than atmospheric pressure using the gas introduction unit and the pressure adjusting unit, so that the adverse effect can be suppressed.

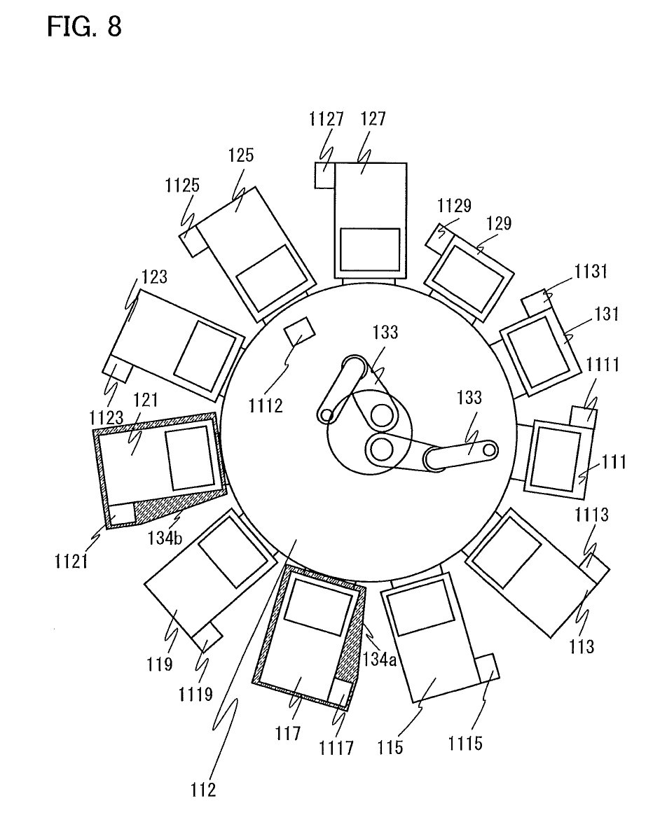

Note that as illustrated in FIG. 8, the third deposition chamber 117 in which an oxide semiconductor film is deposited may be enclosed by a partition 134a, and similarly, the fourth deposition chamber 121 may be enclosed by a partition 134b. With such a structure, the deposition apparatus can have a smaller size than a deposition apparatus having the structure illustrated in FIG. 2.

As described above, the deposition apparatus of this embodiment includes a space into which a sealing gas containing a rare gas can be introduced and which is provided by the partition for separating the air, and the transfer chamber, the deposition chambers, the heating chambers, the treatment chamber, and the substrate standby chamber. A sealing gas whose main component is a gas, in which the concentration of a compound containing a hydrogen atom is 1 ppm or lower, e.g., a rare gas, is introduced into the space, and the pressure in the space is adjusted to atmospheric pressure or a higher pressure, whereby the compound containing a hydrogen atom can be prevented from entering the transfer chamber, the deposition chambers, the heating chambers, the treatment chamber, and the substrate standby chamber.

An oxide semiconductor film and a film in contact with the oxide semiconductor film are successively formed without being exposed to the air with such an apparatus for successive deposition, whereby a compound containing a hydrogen atom is not mixed into the oxide semiconductor film, the film in contact with the oxide semiconductor, and an interface therebetween, and highly purified oxide semiconductor films each of which has sufficiently reduced hydrogen atom concentration can be stacked. Further, a semiconductor device can be manufactured using the stacked film. Such a highly purified oxide semiconductor film is used for a transistor, so that a transistor with low off-state current and low power consumption can be provided.

### Embodiment 3

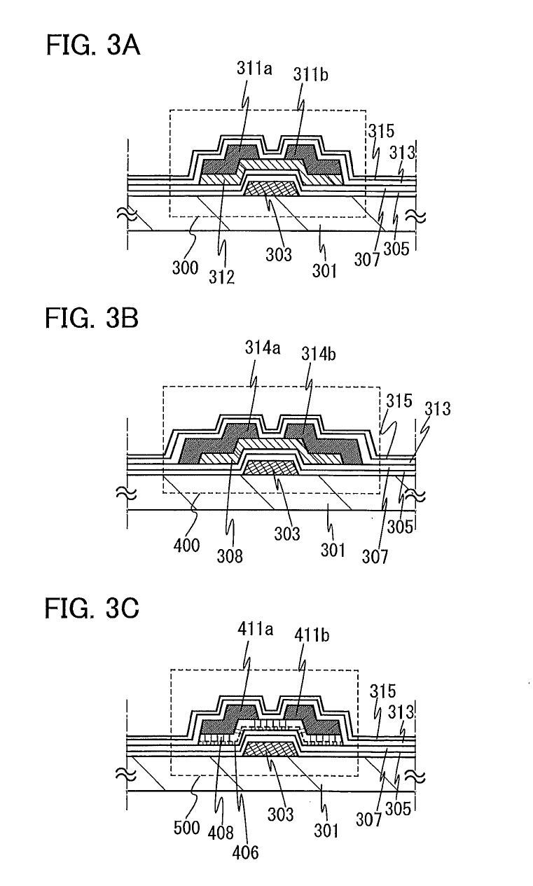

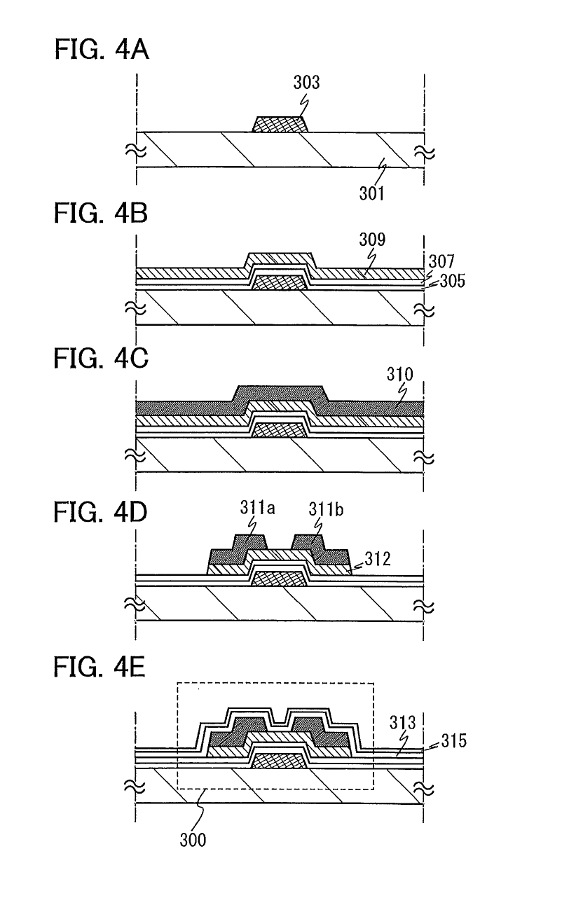

In this embodiment, a method for manufacturing a bottom gate transistor using the apparatus for successive deposition in Embodiment 2 will be described with reference to FIG. 2, FIG. 3A, and FIGS. 4A to 4E. In this embodiment, a method for manufacturing a transistor which uses an oxide semiconductor for a semiconductor layer will be described.

The semiconductor device illustrated in this embodiment includes a highly purified oxide semiconductor layer. With the use of the deposition apparatus illustrated in Embodiment 1 or 2, the oxide semiconductor can be highly purified so as to contain impurities that are not main components of the oxide semiconductor as little as possible, and an i-type (intrinsic) or substantially i-type (intrinsic) oxide semiconductor can be obtained. In other words, a highly purified i-type (intrinsic) oxide semiconductor, or an oxide semiconductor close thereto, is obtained not by adding an impurity but by preventing impurities from being contained in the semiconductor as much as possible. Thus, the transistor manufactured in this embodiment includes an oxide semiconductor layer which is highly purified and made to be electrically i-type (intrinsic).

The number of carriers in the highly purified oxide semiconductor can be significantly small (close to zero). Specifically, the carrier concentration can be reduced to lower than 1×10¹²/cm³, preferably lower than 1×10¹¹/cm³. Further, the hydrogen concentration in the highly purified oxide semiconductor is lower than 1×10¹⁶ atoms/cm³.

With the use of the deposition apparatus illustrated in Embodiment 1 or 2, the number of carriers in the oxide semiconductor can be significantly small. In a transistor in which such a highly purified oxide semiconductor layer is used for a channel formation region, the current value in an off state, i.e., off-state current, can be reduced. Note that it is preferable that off-state current be as low as possible because power consumption can be reduced.

A cross-sectional view of a bottom gate transistor 300 in this embodiment is illustrated in FIG. 3A. The transistor 300 includes a gate electrode layer 303, a first gate insulating layer 305, a second gate insulating layer 307, a highly purified oxide semiconductor layer 312, a source electrode layer 311a, a drain electrode layer 311b, an insulating layer 313, and a protective insulating layer 315.

A method for manufacturing the transistor 300 with the use of the apparatus for successive deposition illustrated in Embodiment 2 will be described with reference to FIGS. 4A to 4E.

First, a conductive film is formed over a substrate 301; a resist mask is formed using a first photomask; and etching is performed, whereby the gate electrode layer 303 is formed (FIG. 4A).

Although there is no particular limitation on a substrate used for the substrate 301, a glass substrate of barium borosilicate glass, aluminoborosilicate glass, or the like is used.

Note that an insulating layer serving as a base may be provided between the substrate 301 and the gate electrode layer 303. The insulating layer has a function of preventing diffusion of an impurity element (for example, an alkali metal such as Li or Na, or an alkaline earth metal such as Ca) from the substrate 301, and can be formed with a single-layer structure or a stacked-layer structure using one or more of a silicon nitride film, a silicon oxide film, a silicon nitride oxide film, and a silicon oxynitride film.

A conductive film which serves as the gate electrode layer 303 can be formed to have a single layer or a stacked layer using a metal material such as molybdenum, titanium, chromium, tantalum, tungsten, aluminum, copper, neodymium, or scandium, or an alloy material or a conductive oxide which contains any of these materials as a main component.

In the case where copper is used for the gate electrode layer, a structure in which a Cu—Mg—Al alloy is provided over the layer serving as a base and copper is provided thereover is preferable. The provision of the Cu—Mg—Al alloy has an effect in enhancing adhesiveness between copper and the base such as an oxide film.

The gate electrode layer can be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

In addition, a material layer in contact with a gate insulating layer may be provided between the gate electrode layer and the gate insulating layer. As the material layer in contact with the gate insulating layer, an In—Ga—Zn—O film containing nitrogen, an In—Sn—O film containing nitrogen, an In—Ga—O film containing nitrogen, an In—Zn—O film containing nitrogen, a Sn—O film containing nitrogen, an In—O film containing nitrogen, a metal nitride film (InN, ZnN, or the like) can be used. These films each have a work function of 5 eV or higher, preferably 5.5 eV or higher; thus, the threshold voltage of the electrical characteristics of the transistor can be positive. Accordingly, a so-called normally-off switching element can be obtained.

For example, in the case of using an In—Ga—Zn—O film containing nitrogen, an In—Ga—Zn—O film having a nitrogen concentration higher than at least the oxide semiconductor layer, or specifically, an In—Ga—Zn—O film having a nitrogen concentration of 7 at. % or higher is used.

With the use of the apparatus for successive deposition (see FIG. 2) in Embodiment 2, the gate insulating layer, the oxide semiconductor film, and the conductive film are deposited successively without being exposed to the air.

First, with a gas introduction unit provided for the partition 134, a sealing gas containing argon, in which the concentration of a compound containing a hydrogen atom is 1 ppm or lower, is introduced into the space 135. At the same time, with a pressure adjusting unit, the pressure in the space 135 is adjusted to atmospheric pressure or a higher pressure. By adjusting the pressure in the space 135 to atmospheric pressure or a higher pressure, entry of a compound containing a hydrogen atom into the space 135 can be suppressed.

Note that argon is used here as the sealing gas; however, this embodiment is not limited thereto, and another rare gas can be used.

Next, the substrate 301 over which the gate electrode layer 303 is formed in advance is transferred to the first load lock chamber 111 in the apparatus for successive deposition. Then, the pressure in the first load lock chamber 111 is reduced using the evacuation unit 1111. Further, the substrate 301 is preheated with the substrate heating unit, and impurities attached to the substrate 301 (e.g., a hydrogen atom and a compound containing a hydrogen atom such as H₂O) are detached and removed.

In the apparatus for successive deposition, the substrate 301 is transferred from one chamber to another chamber through the transfer chamber 112. The transfer chamber 112 is evacuated to a vacuum level using the evacuation unit 1112 such as a cryopump. Note that by filling the space 135 with argon, the impurity concentration in a gas which leaks to the inside of the transfer chamber 112 through a connection portion of the apparatus or a joint portion between pipes provided for the apparatus is extremely reduced. Accordingly, the inside of the transfer chamber 112 is extremely clean with reduced impurities. Further, the inner wall of the apparatus is heated regularly, and impurities adsorbed onto the inner wall are detached; accordingly, a high vacuum level can be achieved.

The substrate 301 is transferred to the first deposition chamber 113 using the substrate transfer unit 133. Then, a high-purity sputtering gas is introduced while the pressure in the first deposition chamber 113 is controlled using the evacuation unit 1113 such as a cryopump, and a silicon nitride film which is to be the first gate insulating layer 305 is deposited over the substrate 301 and the gate electrode layer 303 by a sputtering method. After the deposition, the pressure in the first deposition chamber 113 is evacuated again using the evacuation unit 1113, and the inside of the first deposition chamber 113 is kept clean. By keeping the inside of the first deposition chamber 113 clean after the deposition, whereby impurities contained in the first gate insulating layer 305 and an interface with the first gate insulating layer 305 are effectively reduced.

Then, the substrate 301 is transferred from the first deposition chamber 113 to the second deposition chamber 115, and a silicon oxide film is deposited over the first gate insulating layer 305 by a sputtering method, so that the second gate insulating layer 307 is formed. Before and after the deposition, the inside of the second deposition chamber 115 is evacuated using the evacuation unit 1115 and is kept clean.

The oxide semiconductor used for the semiconductor device manufactured in this embodiment, which is made to be i-type or substantially i-type, is highly sensitive to an interface state and interface charge; thus, an interface between the oxide semiconductor layer and the gate insulating layer is important in controlling the characteristics of the semiconductor device. Therefore, the second gate insulating layer 307 in contact with the highly purified oxide semiconductor is required to be a high quality insulating layer without containing impurities and fixed charge. By filling the space 135 with argon, the impurity concentration in a gas which leaks to the inside of the first deposition chamber 113 and the inside of the second deposition chamber 115 through a connection portion of the apparatus or a joint portion between pipes provided for the apparatus is extremely reduced. Accordingly, the inside of the first deposition chamber 113 and the inside of the second deposition chamber 115 are extremely clean with reduced impurities. The silicon nitride film and the silicon oxide film stacked in such deposition chambers serve as the gate insulating layer with reduced impurity concentration.

In this embodiment, the gate insulating layer is formed to have a stacked-layer structure of a silicon nitride film and a silicon oxide film; however, the gate insulating layer is not limited thereto. The gate insulating layer can have a single-layer or stacked-layer structure including a silicon nitride film, a silicon oxide film, a silicon oxynitride film, a silicon nitride oxide film, an aluminum oxide film, or the like. An oxide insulating film is preferably used as a layer in contact with the oxide semiconductor layer to be formed later. The gate insulating layer can be formed by a plasma CVD method, a sputtering method, or the like. In order to prevent the gate insulating layer from containing a large amount of hydrogen, the gate insulating layer is preferably deposited by a sputtering method. There is no particular limitation on the thickness of the gate insulating layer; the thickness can be greater than or equal to 10 nm and less than or equal to 500 nm, for example.

Next, the substrate 301 is transferred from the second deposition chamber 115 to the third deposition chamber 117, and an oxide semiconductor film 309 is deposited over the second gate insulating layer 307 by a sputtering method. Before and after the deposition, the third deposition chamber 117 is evacuated to a vacuum level using the evacuation unit 1117. By filling the space 135 with argon, the impurity concentration in a gas which leaks to the inside of the third deposition chamber 117 through a connection portion of the apparatus or a joint portion between pipes provided for the apparatus is extremely reduced. Accordingly, the inside of the third deposition chamber 117 is extremely clean with reduced impurities. Impurities contained in the oxide semiconductor film 309 are effectively reduced because the oxide semiconductor film 309 is deposited in the deposition chamber which is kept clean before and after the deposition.

As an oxide semiconductor used for the oxide semiconductor film 309, the following can be used: a four-component metal oxide such as an In—Sn—Ga—Zn—O-based oxide semiconductor; a three-component metal oxide such as an In—Ga—Zn—O-based oxide semiconductor, an In—Sn—Zn—O-based oxide semiconductor, an In—Al—Zn—O-based oxide semiconductor, a Sn—Ga—Zn—O-based oxide semiconductor, an Al—Ga—Zn—O-based oxide semiconductor, or a Sn—Al—Zn—O-based oxide semiconductor; a two-component metal oxide such as an In—Zn—O-based oxide semiconductor, a Sn—Zn—O-based oxide semiconductor, an Al—Zn—O-based oxide semiconductor, a Zn—Mg—O-based oxide semiconductor, a Sn—Mg—O-based oxide semiconductor, an In—Mg—O-based oxide semiconductor, or an In—Ga—O-based oxide semiconductor; an In—O-based oxide semiconductor; a Sn—O-based oxide semiconductor; or a Zn—O-based oxide semiconductor can be used. In addition, any of the above oxide semiconductors may contain an element other than In, Ga, Sn, and Zn, for example, SiO₂. Here, for example, the In—Ga—Zn—O-based oxide semiconductor means an oxide containing at least In, Ga, and Zn, and the composition ratio of the elements is not particularly limited. The In—Ga—Zn—O-based oxide semiconductor may contain an element other than In, Ga, and Zn.

The oxide semiconductor film is non-single-crystal and the oxide semiconductor film is not entirely in an amorphous state. Since the oxide semiconductor film is not entirely in an amorphous state, formation of an amorphous portion whose electrical characteristics are unstable is suppressed.

As the oxide semiconductor film 309, a thin film represented by InMO₃(ZnO)ₘ (m>0, and in is not a natural number) can be used. Here, M represents one or more metal elements selected from Ga, Al, Mn, and Co. For example, M can be Ga, Ga and Al, Ga and Mn, Ga and Co, or the like.

When an In—Zn—O-based material is used as an oxide semiconductor, as the composition ratio of a target to be used, the atomic ratio of In to Zn is 50:1 to 1:2 (the molar ratio of In₂O₃ to ZnO is 25:1 to 1:4), preferably 20:1 to 1:1 (the molar ratio of In₂O₃ to ZnO is 10:1 to 2:1), more preferably 15:1 to 1.5:1 (the molar ratio of In₂O₃ to ZnO is 15:2 to 3:4). For example, when a target used for forming the In—Zn—O-based oxide semiconductor has the following atomic ratio: the atomic ratio of In:Zn:O is X:Y:Z, Z>(1.5X+Y).

In this embodiment, the oxide semiconductor film 309 is deposited by a sputtering method with the use of an In—Ga—Zn—O-based oxide target. A cross-sectional view of this stage is illustrated in FIG. 4B. The oxide semiconductor film 309 can be formed in a rare gas (typically, argon) atmosphere, an oxygen atmosphere, or a mixed atmosphere containing a rare gas and oxygen.

As a target for forming the oxide semiconductor film 309 by a sputtering method, for example, a target having the following composition ratio can be used: the composition ratio of In₂O₃:Ga₂O₃:ZnO is 1:1:1 [molar ratio] (i.e., In:Ga:Zn=1:1:0.5 [atomic ratio]). Alternatively, a target having a composition ratio of In:Ga:Zn=1:1:1 [atomic ratio] or In:Ga:Zn=1:1:2 [atomic ratio] may be used. The filling rate of the oxide target is higher than or equal to 90.0% and lower than or equal to 100%, preferably higher than or equal to 95.0% and lower than or equal to 99.9%. By using the metal oxide target with high filling rate, a dense oxide semiconductor film is formed. Moreover, the purity of the target is preferably higher than or equal to 99.99%, where it is preferable that impurities, for example, an alkali metal such as Li or Na and an alkaline earth metal such as Ca, be particularly reduced.

A high-purity gas in which impurities such as hydrogen, water, a hydroxyl group, and hydride are removed is used as the sputtering gas for the deposition of the oxide semiconductor film 309.

As an example of the deposition conditions, the distance between the substrate and the target is 100 mm, the pressure is 0.6 Pa, the direct-current (DC) power is 0.5 kW, and the atmosphere is an oxygen atmosphere (the proportion of the oxygen flow rate is 100%). Note that a pulse direct current power source is preferable because powder substances (also referred to as particles or dust) generated during the deposition can be reduced and the film thickness can be uniform. The substrate is placed in a deposition chamber under reduced pressure, and the substrate temperature is set to higher than or equal to 100° C. and lower than or equal to 600° C., preferably higher than or equal to 150° C. and lower than or equal to 450° C., more preferably higher than or equal to 200° C. and lower than or equal to 400° C. In particular, the range of higher than or equal to 250° C. and lower than or equal to 320° C. is preferable for dehydrogenation. By forming the oxide semiconductor film in a state where the substrate is heated, the concentration of impurities contained in the deposited oxide semiconductor film can be reduced. In addition, damage by sputtering can be reduced.

Note that impurities, for example, an alkali metal such as Li or Na and an alkaline earth metal such as Ca contained in the oxide semiconductor film are preferably reduced. Specifically, the concentrations of Li, Na, and K detected by SIMS are each lower than or equal to 5×10¹⁵ cm⁻³, preferably lower than or equal to 1×10¹⁵ cm⁻³.

An alkali metal and an alkaline earth metal are adverse impurities for the oxide semiconductor and are preferably contained as little as possible. When an insulating film in contact with the oxide semiconductor is an oxide, an alkali metal, in particular, Na diffuses into the oxide and becomes Na⁺. In addition, Na cuts a bond between metal and oxygen or enters the bond in the oxide semiconductor. As a result, transistor characteristics deteriorate (e.g., the transistor becomes normally-on (the shift of a threshold voltage to a negative side) or the mobility is decreased). In addition, this also causes variation in the characteristics. Such a problem is significant especially in the case where the hydrogen concentration in the oxide semiconductor is extremely low. Therefore, the concentration of an alkali metal is strongly required to set to the above value in the case where the hydrogen concentration in the oxide semiconductor is lower than or equal to 5×10¹⁹ cm⁻³, particularly lower than or equal to 5×10¹⁸ cm⁻³.

After the oxide semiconductor film 309 is deposited, oxide radical treatment is preferably performed on the oxide semiconductor film 309. In this embodiment, oxygen radical treatment is performed in the treatment chamber 125. Before and after the deposition, the treatment chamber 125 is evacuated to a vacuum level using the evacuation unit 1125. By filling the space 135 with argon, the impurity concentration in a gas which leaks to the inside of the treatment chamber 125 through a connection portion of the apparatus or a joint portion between pipes provided for the apparatus is extremely reduced. Accordingly, the inside of the treatment chamber 125 is extremely clean with reduced impurities.

Oxygen radicals may be supplied by a plasma generating apparatus including oxygen or an ozone generating apparatus. By exposing a thin film to the produced oxygen radicals or oxygen, the surface of the film can be modified. Instead of the oxygen radical treatment, radical treatment may be performed using argon and oxygen radicals. The radical treatment using argon and oxygen radicals is treatment in which argon gas and oxygen gas are introduced to generate plasma, thereby modifying a surface of a thin film.

An example of the radical treatment using argon and oxygen radicals is described. Argon atoms (Ar) in a reaction space where an electric field is applied to generate discharge plasma are excited or ionized by electrons in the discharge plasma, thereby being converted into argon radicals (Ar*), argon ions (Ar⁺), or electrons. Argon radicals (Ar*), which are in a high-energy metastable state, react with the peripheral atoms of the same kind or of different kinds to be returned to a stable state by exciting or ionizing the atoms, whereby a reaction occurs like an avalanche. If oxygen exists in the periphery at that time, oxygen atoms (O) are excited or ionized to be converted into oxygen radicals (O*) or oxygen ions (O⁺). The oxygen radicals (O*) react with a material on the surface of a thin film that is to be processed. Note that a feature of a radical of an inert gas is to maintain a metastable state for a longer period compared to a radical of a reactive gas; accordingly, an inert gas is generally used to generate plasma.

Next, the substrate 301 is transferred to the fifth deposition chamber 127, and a conductive film 310 is deposited over the oxide semiconductor film 309 by a sputtering method (FIG. 4C). Before and after the deposition, the fifth deposition chamber 127 is evacuated to a vacuum level using the evacuation unit 1127. By filling the space 135 with argon, the impurity concentration in a gas which leaks to the inside of the fifth deposition chamber 127 through a connection portion of the apparatus or a joint portion between pipes provided for the apparatus is extremely reduced. Accordingly, the inside of the fifth deposition chamber 127 is extremely clean with reduced impurities.

Further, as a material for the conductive film, an element selected from Al, Cr, Cu, Ta, Ti, Mo, and W, an alloy containing any of the above elements as a component, an alloy containing any of the above elements in combination, or the like can be used, for example. Further, a structure may be employed in which a high-melting-point metal film such as a Ti film, a Mo film, a W film, or the like is stacked on one or both of a top surface and a bottom surface of a metal film such as an Al film, a Cu film, or the like. When an Al material to which an element (e.g., Si, Nd, or Sc) which prevents generation of hillocks and whiskers in an Al film is added is used, heat resistance can be increased. Alternatively, the conductive film may be formed using a conductive metal oxide. As the conductive metal oxide, indium oxide (In₂O₃), tin oxide (SnO₂), zinc oxide (ZnO), indium oxide-tin oxide alloy (In₂O₃—SnO₂, which is abbreviated to ITO), indium oxide-zinc oxide alloy (In₂O₃—ZnO), or any of these metal oxide materials in which silicon oxide is contained can be used.

Next, the substrate 301 on which successive deposition process is finished is transferred to the second load lock chamber 131 to perform treatment outside the apparatus for successive deposition. After the pressure in the second load lock chamber 131 is returned to atmospheric pressure, the substrate is transferred from the second load lock chamber 131.

In the successive deposition process, in the case where a substrate transferred from one chamber is required to be on standby before being transferred to another chamber where next deposition and treatment are performed, the substrate can be transferred to the substrate standby chamber 129. The substrate standby chamber 129 is evacuated to a vacuum level using the evacuation unit 1129. By filling the space 135 with argon, the impurity concentration in a gas which leaks to the inside of the substrate standby chamber 129 through a connection portion of the apparatus or a joint portion between pipes provided for the apparatus is extremely reduced. Accordingly, the inside of the substrate standby chamber 129 is extremely clean with reduced impurities.

Next, a resist mask is formed using a second photomask over the conductive film 310, and unnecessary portions of the conductive film 310 and the oxide semiconductor film 309 are removed by etching. Then, using a third photomask, the conductive film overlapping with the channel formation region of the oxide semiconductor layer is etched so that the source electrode layer 311a and the drain electrode layer 311b are formed. Note that the cross-sectional view at this stage is illustrated in FIG. 4D.

Next, the oxide semiconductor layer is subjected to first heat treatment. The oxide semiconductor layer can be dehydrated or dehydrogenated by this first heat treatment. The temperature of the first heat treatment is higher than or equal to 400° C. and lower than or equal to 750° C., or higher than or equal to 400° C. and lower than the strain point of the substrate. Here, the substrate is introduced into an electric furnace which is one of heat treatment apparatuses, and heat treatment is performed on the oxide semiconductor layer in a nitrogen atmosphere at 450° C. for one hour; thus, an oxide semiconductor layer 312 is obtained.

Further, a heat treatment apparatus used is not limited to an electric furnace, and a device for heating an object to be processed by heat conduction or heat radiation from a heating element such as a resistance heating element may be alternatively used. For example, a rapid thermal anneal (RTA) apparatus such as a gas rapid thermal anneal (GRTA) apparatus or a lamp rapid thermal anneal (LRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the high-temperature gas, an inert gas which does not react with an object to be processed by heat treatment, such as nitrogen or a rare gas like argon, is used.

For example, as the first heat treatment, GRTA by which the substrate is moved into an inert gas heated to a high temperature as high as 650° C. to 700° C., heated for several minutes, and moved out of the inert gas heated to the high temperature may be performed.

Note that in the first heat treatment, it is preferable that water, hydrogen, and the like be not contained in the atmosphere of nitrogen or a rare gas such as helium, neon, or argon. It is preferable that the purity of nitrogen or the rare gas such as helium, neon, or argon which is introduced into a heat treatment apparatus be set to 6N (99.9999%) or higher, preferably 7N (99.99999%) or higher (that is, the impurity concentration is 1 ppm or lower, preferably 0.1 ppm or lower).

After the oxide semiconductor layer is heated in the first heat treatment, a high-purity oxygen gas, a high-purity N₂O gas, or ultra-dry air (having a dew point lower than or equal to −40° C., preferably lower than or equal to −60° C.) may be introduced into the furnace. It is preferable that the oxygen gas and the N₂O gas do not contain water, hydrogen, and the like. The purity of the oxygen gas or the N₂O gas which is introduced into the heat treatment apparatus is preferably 6N or higher, more preferably 7N or higher (i.e., the impurity concentration in the oxygen gas or the N₂O gas is preferably 1 ppm or lower, more preferably 0.1 ppm or lower). Oxygen which is a main component of an oxide semiconductor and has been reduced because of the step of removing impurities through the dehydration or the dehydrogenation is supplied with the use of an effect of an oxygen gas or an N₂O gas, whereby the purity of the oxide semiconductor layer is increased and the oxide semiconductor layer is made to be electrically i-type (intrinsic).

Next, the substrate 301 may be transferred from the first load lock chamber 111 again, the substrate may be preheated, and then, plasma treatment may be performed using a gas such as N₂O, N₂, or Ar in the treatment chamber 125 so that water or the like adsorbed onto a surface of an exposed portion of the oxide semiconductor layer is removed. In the case where the plasma treatment is performed, the insulating layer 313 can be formed as a protective insulating layer in contact with part of the oxide semiconductor layer without being exposed to the air.

The insulating layer 313 can be formed to a thickness of at least 1 nm by a method by which impurities such as water and hydrogen are not mixed into the insulating layer 313, such as a sputtering method as appropriate. When hydrogen is contained in the insulating layer 313, the entry of the hydrogen into the oxide semiconductor layer or the extraction of oxygen in the oxide semiconductor layer by hydrogen is caused, thereby making the resistance of the backchannel of the oxide semiconductor layer 312 low (to have an n-type conductivity), so that a parasitic channel might be formed. Therefore, it is important that a deposition method in which hydrogen is not used be employed in order that the insulating layer 313 contains as little hydrogen as possible.

The insulating layer 313 is deposited in the first deposition chamber 113. The first deposition chamber 113 is evacuated to a vacuum level using the evacuation unit 1113. By filling the space 135 with argon, the impurity concentration in a gas which leaks to the inside of the deposition chamber through a connection portion of the apparatus or a joint portion between pipes provided for the apparatus is extremely reduced. Accordingly, the inside of the deposition chamber is extremely clean with reduced impurities.

The insulating layer 313 formed in contact with the oxide semiconductor layer 312 does not contain impurities such as moisture, hydrogen ions, and OH⁻ and is formed using an inorganic insulating film which prevents entry of these from the outside. In particular, an oxide insulating film is preferably used. The insulating layer 313 is formed using, typically a silicon oxide film, a silicon oxynitride film, an aluminum oxide film, an aluminum oxynitride film, or the like.

In this embodiment, a 200-nm-thick silicon oxide film is deposited as the insulating layer 313 by a sputtering method. The substrate temperature at the time of deposition is higher than or equal to room temperature and lower than or equal to 500° C. The silicon oxide film can be formed by a sputtering method in a rare gas (typically argon) atmosphere, an oxygen atmosphere, or a mixed atmosphere containing a rare gas and oxygen. It is preferable that a high-purity gas from which impurities such as hydrogen, water, a hydroxyl group, and hydride are removed be used as the sputtering gas for the deposition of the insulating layer 313. As a sputtering target, a silicon oxide target or a silicon target can be used. For example, a silicon oxide film can be formed by a sputtering method using a silicon target in an atmosphere containing oxygen.

Next, second heat treatment is performed in the first heating chamber 119. Note that the first heating chamber 119 is evacuated to a vacuum level using the evacuation unit 1119. By filling the space 135 with argon, the impurity concentration in a gas which leaks to the inside of the heating chamber through a connection portion of the apparatus or a joint portion between pipes provided for the apparatus is extremely reduced. Accordingly, the inside of the heating chamber is extremely clean with reduced impurities. The second heat treatment is performed in an inert gas atmosphere or in an oxygen gas atmosphere preferably at higher than or equal to 200° C. and lower than or equal to 400° C., for example, at higher than or equal to 250° C. and lower than or equal to 350° C. For example, the second heat treatment is performed in a nitrogen atmosphere at 250° C. for one hour. Through the second heat treatment, part of the oxide semiconductor layer (a channel formation region) is heated while being in contact with the insulating layer 313.

As described above, impurities such as hydrogen, moisture, a hydroxyl group, or a hydride (also referred to as a hydrogen compound) are intentionally removed from the oxide semiconductor layer by subjecting the oxide semiconductor layer to the first heat treatment, and then oxygen which is one of main components of the oxide semiconductor can be supplied because oxygen is reduced in the step of removing impurities. Thus, the oxide semiconductor layer is highly purified to an electrically i-type (intrinsic) oxide semiconductor.

A protective insulating layer 315 may be additionally formed over the insulating layer 313. For example, a silicon nitride film is formed by an RF sputtering method. Since an RF sputtering method has high productivity, it is preferably used as a deposition method of the protective insulating layer. As the protective insulating layer, an inorganic insulating film which does not contain impurities such as moisture and prevents entry of these from the outside, such as a silicon nitride film or an aluminum nitride film is used. In this embodiment, the protective insulating layer 315 is formed using a silicon nitride film.

As in the case of the deposition of the insulating layer 313, the deposition chamber 113 where the protective insulating layer 315 is deposited is evacuated to a vacuum level using the evacuation unit 1113. By filling the space 135 with argon, the impurity concentration in a gas which leaks to the inside of the deposition chamber through a connection portion of the apparatus or a joint portion between pipes provided for the apparatus is extremely reduced. Accordingly, the inside of the deposition chamber is extremely clean with reduced impurities.

Through the above-described steps, the transistor 300 is formed. Note that FIG. 4E is a cross-sectional view at this stage.

As described above, by manufacturing a transistor using the apparatus for successive deposition in Embodiment 2, impurities are not mixed into the oxide semiconductor layer, a layer in contact with the oxide semiconductor, and an interface therebetween, whereby a transistor including a highly purified oxide semiconductor layer in which the hydrogen atom concentration is sufficiently reduced can be manufactured. Further, impurities in the layer in contact with the oxide semiconductor layer are reduced; thus the oxide semiconductor layer can be kept highly purified. A transistor including a highly purified oxide semiconductor layer manufactured by the method described in this embodiment has low off-state current, and by using this transistor, a semiconductor device with low power consumption can be achieved.

### Embodiment 4

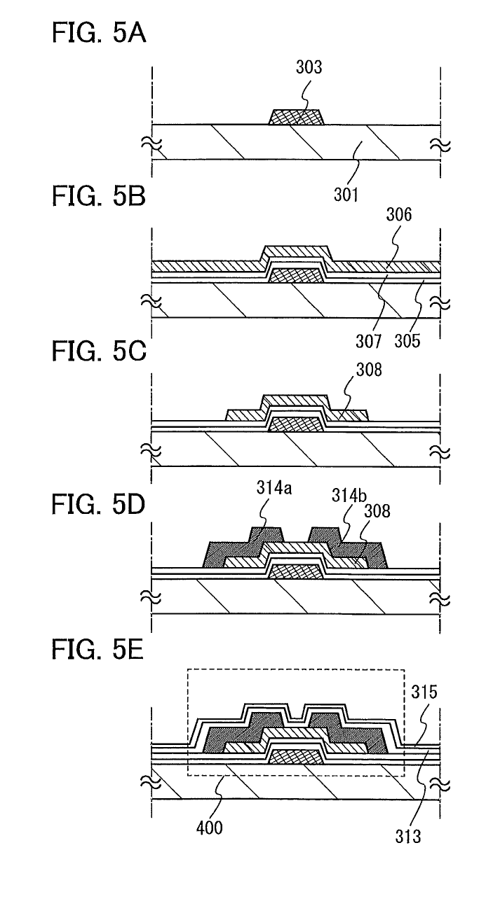

In this embodiment, a method for manufacturing a transistor having a different structure from the transistor described in Embodiment 3 by using the apparatus for successive deposition described in Embodiment 2 will be described with reference to FIG. 2, FIG. 3B, and FIGS. 5A to 5E. In this embodiment, a method for manufacturing a semiconductor device including an oxide semiconductor layer will be described.

A cross-sectional view of a bottom gate transistor 400 in this embodiment is illustrated in FIG. 3B. The transistor 400 includes the gate electrode layer 303, the first gate insulating layer 305, the second gate insulating layer 307, a highly purified oxide semiconductor layer 308, a source electrode layer 314a, a drain electrode layer 314b, the insulating layer 313, and the protective insulating layer 315.

A method for manufacturing the transistor 400 using the apparatus for successive deposition in Embodiment 2 will be described with reference to FIGS. 5A to 5E. First, in a manner similar to that in Embodiment 3, a conductive film is formed over the substrate 301 and a resist mask is formed using a first photomask, so that the gate electrode layer 303 is formed by etching. Note that FIG. 5A is a cross-sectional view at this stage.

Next, using the apparatus for successive deposition in Embodiment 2 (see FIG. 2), the gate insulating layer (the first gate insulating layer 305 and the second gate insulating layer 307) and the oxide semiconductor film 306 are deposited successively without being exposed to the air. The gate insulating layer and the oxide semiconductor film 306 may be deposited in a manner similar to that in Embodiment 3. Note that FIG. 5B is a cross-sectional view at this stage.

Next, outside the apparatus for successive deposition, a resist mask is formed using a second photomask, and the oxide semiconductor film 306 is processed into an island-shaped oxide semiconductor layer 308 through a photolithography step. The resist mask for forming the oxide semiconductor layer 308 may be formed by an inkjet method. Formation of the resist mask by an inkjet method needs no photomask; thus, manufacturing cost can be reduced. Note that FIG. 5C is a cross-sectional view at this stage.

For this etching of the oxide semiconductor film 306, dry etching, wet etching, or both of them may be employed. As an etchant used for wet etching of the oxide semiconductor film 306, for example, a mixed solution of phosphoric acid, acetic acid, and nitric acid, or the like can be used. In addition, ITO07N (produced by KANTO CHEMICAL CO., INC.) may also be used.

Next, the oxide semiconductor layer is subjected to first heat treatment. The oxide semiconductor layer can be dehydrated or dehydrogenated by this first heat treatment. The temperature of the first heat treatment is higher than or equal to 400° C. and lower than or equal to 750° C., or higher than or equal to 400° C. and lower than the strain point of the substrate. Here, the substrate is introduced into an electric furnace which is one of heat treatment apparatuses, and heat treatment is performed on the oxide semiconductor layer in a nitrogen atmosphere at 450° C. for one hour. Then, the oxide semiconductor layer is not exposed to the air so that entry of water and hydrogen into the oxide semiconductor layer is prevented. Thus, the oxide semiconductor layer 308 is obtained.

Further, a heat treatment apparatus used is not limited to an electric furnace, and a device for heating an object to be processed by heat conduction or heat radiation from a heating element such as a resistance heating element may be alternatively used. For example, a rapid thermal anneal (RTA) apparatus such as a gas rapid thermal anneal (GRTA) apparatus or a lamp rapid thermal anneal (LRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the high-temperature gas, an inert gas which does not react with an object to be processed by heat treatment, such as nitrogen or a rare gas like argon, is used.

For example, as the first heat treatment, GRTA by which the substrate is moved into an inert gas heated to a high temperature as high as 650° C. to 700° C., heated for several minutes, and moved out of the inert gas heated to the high temperature may be performed.

Note that in the first heat treatment, it is preferable that water, hydrogen, and the like be not contained in the atmosphere of nitrogen or a rare gas such as helium, neon, or argon. It is preferable that the purity of nitrogen or the rare gas such as helium, neon, or argon which is introduced into a heat treatment apparatus be set to 6N (99.9999%) or higher, preferably 7N (99.99999%) or higher (that is, the impurity concentration is 1 ppm or lower, preferably 0.1 ppm or lower).

After the oxide semiconductor layer is heated in the first heat treatment, a high-purity oxygen gas, a high-purity N₂O gas, or ultra-dry air (having a dew point lower than or equal to −40° C., preferably lower than or equal to −60° C.) may be introduced into the furnace. It is preferable that the oxygen gas and the N₂O gas do not contain water, hydrogen, and the like. The purity of the oxygen gas or the N₂O gas which is introduced into the heat treatment apparatus is preferably 6N or higher, more preferably 7N or higher (i.e., the impurity concentration in the oxygen gas or the N₂O gas is preferably 1 ppm or lower, more preferably 0.1 ppm or lower). Oxygen which is a main component of an oxide semiconductor and has been reduced because of the step of removing impurities through the dehydration or the dehydrogenation is supplied with the use of an effect of an oxygen gas or an N₂O gas, whereby the purity of the oxide semiconductor layer is increased and the oxide semiconductor layer is made to be electrically i-type (intrinsic).

The first heat treatment of the oxide semiconductor layer may be performed on the oxide semiconductor film which has not yet been processed into the island-shaped oxide semiconductor layer. In that case, the substrate is taken out from the heat treatment apparatus after the first heat treatment, and then a photolithography step is performed.

Note that the first heat treatment may be performed at either of the following timings without limitation to the above-described timing as long as it is performed after the oxide semiconductor film is formed: after a source electrode layer and a drain electrode layer are formed over the oxide semiconductor layer; and after an insulating layer is formed over the source electrode layer and the drain electrode layer.

In the case where a contact hole is formed in the gate insulating layer, the formation of the contact hole may be performed before or after the first heat treatment is performed on the oxide semiconductor layer.

Next, a conductive film is deposited over the second gate insulating layer 307 and the oxide semiconductor layer 308 by a sputtering method. Then, a resist mask is formed over the conductive film using a third photomask and selective etching is performed, so that the source electrode layer 314a and the drain electrode layer 314b are formed. Note that FIG. 5D is a cross-sectional view at this stage.

After that, by plasma treatment using a gas such as N₂O, N₂, or Ar, water or the like adsorbed onto a surface of an exposed portion of the oxide semiconductor layer may be removed.

Then, in a manner similar to that in Embodiment 2, a silicon oxide film is deposited as the insulating layer 313 in contact with part of the oxide semiconductor layer and a silicon nitride film is deposited as the protective insulating layer 315 over the insulating layer 313.

Next, second heat treatment (preferably at higher than or equal to 200° C. and lower than or equal to 400° C., for example, higher than or equal to 250° C. and lower than or equal to 350° C.) is performed in an inert gas atmosphere or an oxygen gas atmosphere. For example, the second heat treatment is performed in a nitrogen atmosphere at 250° C. for one hour. In the second heat treatment, part of the oxide semiconductor layer (a channel formation region) is heated while being in contact with the insulating layer 313.

Through the above steps, the transistor 400 is formed. Note that FIG. 5E is a cross-sectional view at this stage.

As described above, by manufacturing a transistor using the apparatus for successive deposition in Embodiment 2, impurities are not mixed into the oxide semiconductor layer, a layer in contact with the oxide semiconductor, and an interface therebetween, whereby a transistor including a highly purified oxide semiconductor layer in which the hydrogen atom concentration is sufficiently reduced can be manufactured. Further, impurities in the gate insulating layer and the conductive layer which are in contact with the oxide semiconductor layer are reduced; thus the oxide semiconductor layer can be kept highly purified. A transistor including a highly purified oxide semiconductor layer manufactured by the method described in this embodiment has low off-state current, and by using this transistor, a semiconductor device with low power consumption can be achieved.

### Embodiment 5

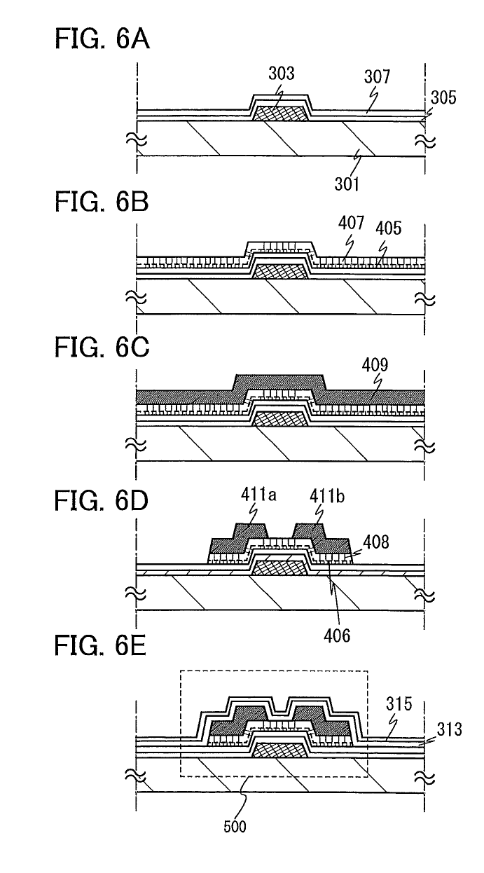

In this embodiment, a method for manufacturing a transistor having a different structure from the semiconductor devices described in Embodiments 3 and 4 by using the apparatus for successive deposition described in Embodiment 2 will be described with reference to FIG. 2, FIG. 3C, and FIGS. 6A to 6E. In this embodiment, in particular, a method for manufacturing a transistor using an oxide semiconductor layer having a crystal region will be described.

A cross-sectional view of a transistor whose manufacturing method is described in this embodiment will be illustrated in FIG. 3C. A transistor 500 includes the gate electrode layer 303, the first gate insulating layer 305, the second gate insulating layer 307, a first oxide semiconductor layer 406, a second oxide semiconductor layer 408, a source electrode layer 411a, a drain electrode layer 411b, the insulating layer 313, and the protective insulating layer 315. Note that the first oxide semiconductor layer 406 and the second oxide semiconductor layer 408 are crystallized.

A method for manufacturing the transistor 500 using the apparatus for successive deposition in Embodiment 2 will be described with reference to FIGS. 6A to 6E.

First, a conductive film is formed over the substrate 301, and then, the gate electrode layer 303 is formed by a first photolithography step.

Next, using the apparatus for successive deposition (see FIG. 2) in Embodiment 2, the first gate insulating layer 305 and the second gate insulating layer 307 are formed. Note that FIG. 6A is a cross-sectional view at this stage.

Next, the substrate 301 is transferred from the second deposition chamber 115 to the third deposition chamber 117, and an oxide semiconductor film having a crystal region is formed over the second gate insulating layer 307. In this embodiment, the oxide semiconductor film is formed by two deposition steps, and heat treatment is performed twice. With such a deposition method, an oxide semiconductor film having a crystal region with a large thickness, that is, a crystal region which is c-axis-aligned perpendicularly to a surface of the film can be formed. By using such a method, a crystal region can be formed in the oxide semiconductor regardless of the material for a base component such as an oxide, a nitride, a metal, or the like.

The first oxide semiconductor film is deposited by a sputtering method. Note that the third deposition chamber 117 where the first oxide semiconductor film is deposited is evacuated to a vacuum level using the evacuation unit. In addition, by filling the space 135 with a sealing gas whose main component is argon, the impurity concentration in a gas which leaks to the inside of the deposition chamber through a connection portion of the apparatus or a joint portion between pipes provided for the apparatus is extremely reduced. Accordingly, the inside of the deposition chamber is extremely clean with reduced impurities.

As the oxide semiconductor used for the first oxide semiconductor film, the oxide semiconductor described in Embodiment 3 can be used.

The first oxide semiconductor film is used as a seed crystal for crystal growth of the second oxide semiconductor film which is formed later. Therefore, the first oxide semiconductor film may have a thickness with which crystal growth is possible, typically greater than or equal to a thickness of one atomic layer and less than or equal to 30 nm, preferably greater than or equal to 2 nm and less than or equal to 5 nm. When the first oxide semiconductor film is thin, throughput in deposition treatment and heat treatment can be improved.

Next, the substrate 301 is transferred from the third deposition chamber 117 to the first heating chamber 119, and subjected to the first heat treatment; accordingly, a crystal region (including a plate-like crystal) is formed in a region including a surface of the first oxide semiconductor film. By the first heat treatment, the first oxide semiconductor film 405 having the crystal region (including a plate-like crystal) in the region including the surface is formed (FIG. 6B).

The first heat treatment is performed in an atmosphere of nitrogen, oxygen, a rare gas, or dry air. In the first heat treatment, a temperature higher than or equal to 450° C. and lower than or equal to 850° C., preferably higher than or equal to 550° C. and lower than or equal to 750° C. is employed. In addition, heating time is longer than or equal to 1 minute and shorter than or equal to 24 hours.

It is preferable that the first heating chamber 119 have a heating unit which can heat a substrate at higher than or equal to room temperature and lower than or equal to 850° C.

Note that in the case where the third deposition chamber 117 has a substrate heating unit, by depositing the first oxide semiconductor film while heating the substrate, crystal growth can be promoted. Crystals in the first oxide semiconductor film are grown during the deposition, whereby the first heat treatment can be omitted. A condition for heating the substrate is that the substrate 301 may be heated at higher than or equal to 450° C. and lower than or equal to 850° C., preferably higher than or equal to 550° C. and lower than or equal to 750° C.

Next, the substrate is transferred from the first heating chamber 119 to the fourth deposition chamber 121, and the second oxide semiconductor film that is thicker than the first oxide semiconductor film is formed by a sputtering method. Note that the fourth deposition chamber 121 where the second oxide semiconductor film is deposited is evacuated to a vacuum level using the evacuation unit. In addition, by filling the space 135 with a sealing gas whose main component is argon, the impurity concentration in a gas which leaks to the inside of the fourth deposition chamber 121 through a connection portion of the apparatus or a joint portion between pipes provided for the apparatus is extremely reduced. Accordingly, the inside of the fourth deposition chamber 121 is extremely clean with reduced impurities.

As an oxide semiconductor used for the second oxide semiconductor film, the oxide semiconductor described in Embodiment 3 can be used.

Note that the thickness of the second oxide semiconductor film may be determined as appropriate in accordance with a device to be manufactured, by a practitioner.

In the case where the fourth deposition chamber 121 includes a substrate heating unit, the second oxide semiconductor film may be formed while the substrate is heated.

Next, the substrate 301 is transferred from the fourth deposition chamber 121 to the second heating chamber 123, and the second heat treatment is performed. Note that the second heating chamber 123 is evacuated to a vacuum level. In addition, by filling the space 135 with a sealing gas whose main component is argon, the impurity concentration in a gas which leaks to the inside of the second heating chamber 123 through a connection portion of the apparatus or a joint portion between pipes provided for the apparatus is extremely reduced. Accordingly, the inside of the second heating chamber 123 is extremely clean with reduced impurities.

The second heat treatment is performed at higher than or equal to 450° C. and lower than or equal to 850° C., preferably higher than or equal to 600° C. and lower than or equal to 700° C. Crystal growth proceeds upward with the use of the first oxide semiconductor film 405 as a seed crystal for the crystal growth and the whole second oxide semiconductor film is crystallized. In such a manner, the second oxide semiconductor film 407 having a crystal region with a large thickness is formed. Note that FIG. 6B is a cross-sectional view at this stage.

Note that the boundary between the first oxide semiconductor film 405 and the second oxide semiconductor film 407 having a crystal region is shown by a dashed line in FIGS. 6B, 6C, 6D, and 6E; however, the boundary between the first oxide semiconductor film 405 and the second oxide semiconductor film 407 having a crystal region cannot be determined and the first oxide semiconductor film 405 and the second oxide semiconductor film 407 can be regarded to as one layer in some cases.

Further, after the first oxide semiconductor film 405 and the second oxide semiconductor film 407 are deposited, oxide radical treatment is preferably performed on the surface of the second oxide semiconductor film 407. In this embodiment, oxygen radical treatment is performed in the treatment chamber 125. The oxide radical treatment can be performed in a manner similar to that in Embodiment 3.

Next, the substrate 301 is transferred to the fifth deposition chamber 127, and a conductive film 409 is deposited over the second oxide semiconductor film 407 by a sputtering method. The conductive film 409 can be formed using a material and a method similar to those of the conductive film 310 in Embodiment 3. Therefore, Embodiment 3 can be referred to for the details. Note that FIG. 6C is a cross-sectional view at this stage.

Then, the substrate 301 on which successive deposition is finished is transferred to the second load lock chamber 131, and the substrate is transferred from the apparatus for successive deposition.

In a manner similar to that in Embodiment 3, the first oxide semiconductor layer 406, the second oxide semiconductor layer 408, the source electrode layer 411a, and the drain electrode layer 411b are formed by a photolithography step using the second photomask and by etching. Note that FIG. 6D is a cross-sectional view at this stage.

Next, using a material and a method similar to those described in Embodiment 3, a silicon oxide film is formed as the insulating layer 313 and a silicon nitride film is deposited as the protective insulating layer 315.

Through the above-described steps, the transistor 500 using an oxide semiconductor layer having a crystal region can be manufactured. Note that FIG. 6E is a cross-sectional view at this stage.

Note that in this embodiment, the case where the oxide semiconductor layer having a crystal region is formed using two oxide semiconductor layers is described; however, the oxide semiconductor layer having a crystal region may have a single layer or three or more layers.

In the case where an oxide semiconductor film having a crystal region is deposited using a single-layer oxide semiconductor film, for example, an oxide semiconductor film may be formed in the third deposition chamber 117 and may be subjected to heat treatment in the first heating chamber 119. Further, the deposition may be performed while the substrate 301 is heated so that crystal growth is promoted. Furthermore, oxide radical treatment may be performed on the oxide semiconductor film which has been deposited, in the treatment chamber 125.

Note that in the case where a transistor is manufactured by the steps of processing an oxide semiconductor film having a crystal region into an island-shaped oxide semiconductor layer having a crystal region and forming a conductive layer thereover, the method described in Embodiment 4 can be applied except for the formation of the oxide semiconductor layer. Therefore, Embodiment 4 can be referred to for the details.

As described above, by manufacturing a transistor using the apparatus for successive deposition in Embodiment 2, impurities are not mixed into the oxide semiconductor layer, a layer in contact with the oxide semiconductor, and an interface therebetween, whereby a transistor including a highly purified oxide semiconductor layer in which the hydrogen atom concentration is sufficiently reduced can be manufactured. Further, impurities in the gate insulating layer and the conductive layer which are in contact with the oxide semiconductor layer are reduced; thus the oxide semiconductor layer can be kept highly purified. A transistor including a highly purified oxide semiconductor layer manufactured by the method described in this embodiment has low off-state current, and by using this transistor, a semiconductor device with low power consumption can be achieved.

This application is based on Japanese Patent Application serial no. 2010-085714 filed with Japan Patent Office on Apr. 2, 2010, the entire contents of which are hereby incorporated by reference.

What is claimed is:

1. A deposition apparatus comprising:
a deposition chamber; and
a partition provided to enclose the deposition chamber so that a space is provided between the deposition chamber and the partition,
wherein the partition comprises a unit for supplying the space with a gas including a compound containing a hydrogen atom, in which a concentration of the compound is lower than or equal to 1 ppm, and a pressure adjusting unit for adjusting a pressure in the space to atmospheric pressure or a higher pressure, and
wherein the deposition chamber comprises a target holding portion for fixing a sputtering target and a vacuum evacuation unit.

2. The deposition apparatus according to claim 1, further comprising a load lock chamber which comprises a substrate holding portion provided with a heating unit for heating a substrate and a vacuum evacuation unit.

3. The deposition apparatus according to claim 1,
wherein a rare gas is contained in the gas, in which the concentration of the compound containing a hydrogen atom is lower than or equal to 1 ppm.

4. The deposition apparatus according to claim 1,
wherein argon is contained in the gas, in which the concentration of the compound containing a hydrogen atom is lower than or equal to 1 ppm.

5. The deposition apparatus according to claim 1,
wherein the sputtering target comprises metal oxide.

6. The deposition apparatus according to claim 1,
wherein the partition is a flexible bag or a chamber.

7. A deposition apparatus comprising:
a plurality of deposition chambers;
a partition provided to enclose at least one of the plurality of deposition chambers so that a space is provided between the at least one of the plurality of deposition chambers and the partition; and
a load lock chamber comprising a substrate holding portion provided with a heating unit for heating a substrate and a vacuum evacuation unit,
wherein the partition comprises a unit for supplying the space with a gas, in which a concentration of a compound containing a hydrogen atom is lower than or equal to 1 ppm, and a pressure adjusting unit for adjusting a pressure in the space to atmospheric pressure or a higher pressure,
wherein the at least one of the plurality of deposition chambers comprises a target holding portion for fixing a sputtering target and a vacuum evacuation unit,
wherein another one of the plurality of deposition chambers comprises a target holding portion for fixing a sputtering target of metal oxide, and
wherein a transfer unit comprising a vacuum evacuation unit and being connected to the load lock chamber and the plurality of deposition chambers through gate valves is provided in the space.

8. The deposition apparatus according to claim 7,
wherein a rare gas is contained in the gas, in which the concentration of the compound containing a hydrogen atom is lower than or equal to 1 ppm.

9. The deposition apparatus according to claim 7,
wherein argon is contained in the gas, in which the concentration of the compound containing a hydrogen atom is lower than or equal to 1 ppm.

10. The deposition apparatus according to claim 7,
wherein the partition is a flexible bag or a chamber.

11. A method for manufacturing a semiconductor device, comprising the steps of:
introducing a substrate into a deposition chamber provided in a space and evacuated to a vacuum level, wherein the space is supplied with a gas including a compound containing a hydrogen atom, a concentration of the compound in the gas is lower than or equal to 1 ppm, and a pressure in the space is kept at atmospheric pressure or a higher pressure;
introducing a high-purity sputtering gas into the deposition chamber; and
forming an oxide semiconductor film over the substrate by a sputtering method.

12. A method for manufacturing a semiconductor device, comprising the steps of:
transferring a substrate to a load lock chamber;
evacuating the load lock chamber to a vacuum level;
performing heat treatment on the substrate;
transferring the substrate to a first deposition chamber provided in a space and evacuated to a vacuum level, wherein the space is supplied with a gas including a compound containing a hydrogen atom, a concentration of the compound in the gas is lower than or equal to 1 ppm, and a pressure in the space is kept at atmospheric pressure or a higher pressure;
introducing a high-purity sputtering gas into the first deposition chamber and forming a gate insulating film over the substrate by a sputtering method;
evacuating the first deposition chamber to a vacuum level;
transferring the substrate to a second deposition chamber provided in the space and evacuated to a vacuum level; and
introducing a high-purity sputtering gas into the second deposition chamber and forming an oxide semiconductor film over the gate insulating film by a sputtering method.

13. The method for manufacturing a semiconductor device according to claim 12, comprising the steps of:
evacuating the second deposition chamber to a vacuum level after the oxide semiconductor film is formed;
transferring the substrate to a third deposition chamber provided in the space and evacuated to a vacuum level; and
introducing a high-purity sputtering gas into the third deposition chamber and forming a conductive film over the oxide semiconductor film by a sputtering method.
